(19) United States
(12) Patent Application Publication
(10) Pub. No.: US 2011/0025327 A1
(43) Pub. Date: Feb. 3, 2011

(54) METHOD FOR RADIOFREQUENCY MAPPING IN MAGNETIC RESONANCE IMAGING

(75) Inventors: Sean C.L. Deoni, London (GB); Steven Williams, London (GB)

Correspondence Address: PATTERSON THUENTE CHRISTENSEN PEDERSEN, P.A., 4800 IDS CENTER, 80 SOUTH 8TH STREET, MINNEAPOLIS, MN, 55402-2100, US

(73) Assignee: KING'S COLLEGE LONDON, London (GB)

(21) Appl. No.: 12/443,673

(22) PCT Filed: Sep. 26, 2007
(86) PCT No.: PCT/GB07/03665

§ 371 Date: Oct. 20, 2010

(30) Foreign Application Priority Data
Sep. 29, 2006 (GB) 0619269.4

(51) Int. Cl. G01R 33/48

(52) U.S. Cl. 324/309

(57) ABSTRACT

A method of mapping a radio frequency magnetic field transmitted to a magnetic resonance imaging specimen. The method comprises the steps of: applying a first radio frequency pulse having a first excitation angle to the specimen and at a first time period after applying the first pulse applying one or more second radio frequency pulses each having a second excitation angle to the specimen, with a second time period between second pulses, to obtain a first data set defining a first sample of an image space; applying one or more third radio frequency pulses each having a third excitation angle to the specimen, with a third time period between third pulses, to obtain a second data set defining a second sample of the image space; applying one or more fourth radio frequency pulses each having a fourth excitation angle to the specimen, with a fourth time period between fourth pulses, to obtain a third data set defining a third sample of the image space; wherein the fourth excitation angle is different to the third excitation angle and/or the fourth time period is different to the third time period; calculating a magnetic field map data from at the three data sets; and outputting the magnetic field map data.

### PRIORITY CLAIM

The present application is a National Phase entry of PCT Application No. PCT/GB2007/003665, filed Sep. 26, 2007, which claims priority from Great Britain Application Number 0619269.4, filed Sep. 29, 2006, the disclosures of which are hereby incorporated by reference herein in their entirety.

### TECHNICAL FIELD

The present invention relates to a method of mapping a radiofrequency (RF) magnetic field (B₁⁺) transmitted to a magnetic resonance imaging (MRI) specimen.

### BACKGROUND

MRI has traditionally been used in clinical applications to acquire images of living tissue which distinguish between pathological tissue and normal tissue. MRI is also used in non-clinical applications to detect geological structures, for example in the oil industry.

The most well established MRI techniques are qualitative T₁ (longitudinal relaxation time) and T₂ (transverse relaxation time) weighted imaging. However, there are many circumstances where it is desirable to use quantitative imaging, that is to determine actual T₁ and/or T₂ values. Such quantitative imaging is generally hypothesized to provide improved sensitivity to tissue biochemical changes associated with disease pathogenesis.

Various methods exist to measure T₁ and T₂ values, but such conventional mapping methods suffer from lengthy scan times and poor spatial resolution and so have limited usefulness, for example in a clinical role. There is therefore a need for faster T₁ and T₂ mapping techniques.

Rapid T₁ and T₂ mapping is also desirable in non-clinical MRI applications, for example in situations such as underground drilling where it is necessary to situate imaging equipment on mobile structures and acquire images with minimum disturbance to movement of these structures.

Recently, a number of rapid methods have been proposed, which have acquisition times similar to routine clinical scans. Such methods for rapid voxel-wise T₁ determination use steady-state imaging methods in which the magnetization is driven into dynamic equilibrium through application of low flip angle (angle of excitation: α), that is generally less than 30 degrees, radio-frequency (RF) pulses separated by short delays times (pulse sequence repetition time (TR) typically between 2 and 10 ms). These methods make it possible to quickly acquire high resolution T₁ images. Depending on the specific steady-state sequence employed, the magnetization may be sampled either once equilibrium has been established, or during the transient phase preceding equilibrium, with the transverse magnetization either spoiled prior to each RF pulse with gradient or RF spoiling (or a combination of the two), or fully refocused.

Although these methods permit rapid T₁ measurement, the accuracy of the derived T₁ estimates depends strongly on correct knowledge of the transmitted flip angle. However, in many circumstances, the spatial homogeneity of the transmitted B₁⁺ RF field cannot be ensured, resulting in the transmitted flip angle varying greatly from the prescribed value throughout the image. This is the case at high field strengths, such as at 3 Tesla (T) where the RF wavelength becomes similar in scale to the imaged object (for example a human head) and the dielectric properties of tissue cause RF shielding. RF inhomogeneity is also encountered (at any field strength) when non-symmetric surface transmit/receive RF coils are employed, such as for extremity (for example knee) imaging. High field scanners, as well as the use of surface coils, are becoming increasingly common in the clinical setting as they provide improved signal-to-noise ratio, allowing for high spatial-resolution imaging. However, even at moderate field strengths, such as 1.5 T, RF inhomogeneity can be problematic in large field-of-view imaging (such as abdominal imaging). In addition to these effects, imperfectly designed RF pulses result in non-uniform flip angle profiles across the two-dimensional (2D) slice or 3D slab, independent of field strength or RF coil. Finally, at all field strengths, a clinical MRI scanner performs an internal calibration at the beginning of every imaging examination, in part to determine the RF power required to transmit a certain flip angle. However, as this calibration is non-specific (i.e. averaged over the whole object) the result represents a global average. Consequently, the RF power requirements may be under- or over estimated in different regions of the object.

While a variety of methods have been proposed to account for, and correct, variations in the transmitted B₁⁺ field, these require lengthy scan times, suffer large-scale geometric distortions, or require high power RF pulses, so are of limited use. Such methods include theoretical modeling of the transmitted field using finite element simulations of the coil and tissue compartments, the use of adiabatic or composite RF pulses which provide more uniform B₁⁺ profiles and mapping the B₁⁺ field from acquired image data.

For example, direct mapping of the transmitted field is appealing as it may be readily incorporated into an imaging experiment (in the form of a set of calibration scans run at the beginning of the session) and does not require a priori knowledge of the tissue and coil geometries or dielectric properties. Direct mapping methods generally involve acquisition of fully-relaxed (TR>>T₁) spin-echo (SE) or gradient-echo (GE) images at two or three flip angles (generally either α and 2α, or α, 2α and 3α). From these data, B₁⁺ can be determined via trigonometric relationships of the signal intensity values. However, such methods are slow due to the need to allow the spin system to fully recover between successive RF pulses, which reduces the practicality of B₁⁺ mapping in large volume, three dimensional (3D) applications.

Although the use of echo-planar imaging (EPI) readout trains can alleviate these time concerns, SE-EPI and GE-EPI suffer susceptibility-induced geometric distortions and signal drop-outs, and are sensitive to main field (Bₒ) inhomogeneities, both of which require additional correction. Further, while these techniques permit compensation for B₁⁺ errors related to dielectric effects, slice and slab profile effects are specific to the RF pulse shape which may vary between the multi-slice 2D SE B₁⁺ correction sequence and the 3D spoiled gradient sequence used for T₁ mapping.

An example of a T₁ mapping method which suffers from the problems discussed above is Driven Equilibrium Single Pulse Observation of T₁ (DESPOT1). (DESPOT1 can also be called variable nutation spoiled gradient recalled echo (SPGR) or the method of variable flip angles). The DESPOT1 method represents one of the most efficient (in terms of signal-to-noise per unit scan time) means of quantifying T₁, but because of the problem of sensitivity to incorrect knowledge of the transmitted flip angle, the method has primarily been limited to lower field strengths, generally 1.5 T and below, where patient-specific B₁⁺ variations due to tissue dielectric effects is small. While DESPOT1 has been successfully applied at higher fields, such as at 9.4 T, the fields of view utilized in these applications have been small enough to justify the assumption of a spatially uniform B; field. High field (3 T and above) large-volume (i.e. whole-brain) T₁ mapping with DESPOT1, however, have remained a challenge.

In the DESPOT1 T₁ mapping method, T₁ is derived from a series of spoiled gradient recalled echo (SPGR) images (data sets) acquired over a range of flip angles (a) with constant repetition time (TR). By re-writing the general SPGR signal equation in the linear form Y=mX+b,

$$\frac{{S}_{SPGR}}{sin {α}_{T}} = \frac{{S}_{SPGR}}{tan {α}_{T}} {E}_{1} + ρ ( 1 - {E}_{1} ) , \qquad [ 1 ]$$

T₁ and ρ may be readily determined from the slope and intercept of the S_{SPGR}/sin α vs. S_{SPGR}/tan α curve as,

T₁=−TR/log(m) [2]

and

ρ=b/(1−m). [3]

In the above expressions, E₁=exp(−TR/T₁), ρ is proportional to the equilibrium longitudinal magnetization (and includes factors such as electronic amplifier gains and receive coil sensitivity effects), and α_{T} is the transmitted flip angle defined by the applied B₁⁺ field.

As T₁ is derived directly from the slope of the S_{SPGR}/sin α vs. S_{SPGR}/tan α line, accurate knowledge of the transmitted flip angles is crucial for correct T₁ determination. While it is conventionally assumed that the transmitted flip angle is equal to the prescribed value (α_{T}=α_{P}) and is spatially homogeneous throughout the image volume, as discussed above these assumptions are true only in a limited range of applications, such as at lower field strengths or with small fields of view. In fact, the transmitted flip angle is usually related to the prescribed value as α_{T}=κα_{P}, where κ denotes the spatially varying B₁⁺ field. Within the context of quantitative imaging, and T₁ mapping via the conventional inversion recovery (IR) approach specifically, an approach often used to account for B₁⁺ deviations is to include the flip angle as an additional parameter in the fitting routine. For example, by calculating the three-parameter fit of

S_{IR}(TI,TR)=ρ[1−βexp(−TI/T₁(−TR/T₁)], [4]

to multiple inversion time (TI), IR data for ρ, T₁ and β, spatial variations in B₁⁺ field are accounted for by the inversion efficiency term, β. Unfortunately, this approach may not always be used directly, for example in the case of DESPOT1, as is demonstrated in FIGS. 1a and 1b. Where this approach may be used directly, for example for multi-point IR-SPGR, such methods are again slow and the maximum resolution at which this approach will work is quite low.

In FIG. 1a, three example S_{SPGR}/sin κα vs. S_{SPGR}/tan κα curves are shown calculated from theoretical SPGR data generated with parameters: T₁=1200 ms, ρ=1000 and =α_{P} 3°, 6°, 9°, 12° and 15°. The difference between each curve is the assumed B₁⁺ (κ) variation used in each calculated, ranging from κ=0.5, 1.0 and 1.5. Although these three curves appear to overlap, as expected, the T₁ and ρ values calculated from each vary greatly. For κ=0.5, T₁=300 ms, ρ=500, for κ=1, T₁=1200 ms, ρ=1000, and for κ=1.5, T₁=2720 ms, ρ=1500. Thus, for any assumed value of κ, a seemingly linear S_{SPGR}/sin κα vs. S_{SPGR}/tan κα curve can be generated and T₁ and ρ calculated. Further, when S_{SPGR} vs. α_{T} curves are calculated using these derived T₁ and ρ values (FIG. 1b) there is close agreement between the theoretical curves and the image data. In FIG. 1b the symbols correspond to the calculated points while the lines correspond to the original data. It can be seen that no unique solution exists for κ, T₁ and ρ to a set of multi-angle DESPOT1 data. Rather, for any value of κ, apparent T₁ and ρ values can be calculated which, when compared with the data show no obvious divergence. It is therefore not possible to include κ as an additional parameter in the DESPOT1 fitting routine.

A means of mapping the B₁⁺ field is needed which addresses the problems with conventional approaches.

### SUMMARY

Embodiments of the invention relate to methods of mapping a radio frequency magnetic field transmitted to a magnetic resonance imaging specimen.

In one embodiment, a method comprises the steps of: applying a first radio frequency pulse having a first excitation angle to the specimen and at a first time period after applying the first pulse applying one or more second radio frequency pulses each having a second excitation angle to the specimen, with a second time period between second pulses, to obtain a first data set defining a first sample of an image space; applying one or more third radio frequency pulses each having a third excitation angle to the specimen, with a third time period between third pulses, to obtain a second data set defining a second sample of the image space; applying one or more fourth radio frequency pulses each having a fourth excitation angle to the specimen, with a fourth time period between fourth pulses, to obtain a third data set defining a third sample of the image space; wherein the fourth excitation angle is different to the third excitation angle and/or the fourth time period is different to the third time period; calculating a magnetic field map data from at the three data sets; and outputting the magnetic field map data.

### BRIEF DESCRIPTION OF THE DRAWINGS

An example of the present invention will now be described with reference to the accompanying drawings, in which:

FIG. 1a is a graph showing that for the conventional DESPOT1 method, for any assumed value of κ (spatial variance of B₁⁺ field) a seemingly linear S_{SPGR}/sin κα vs. S_{SPGR}/tan κα curve can be generated;

FIG. 1b is a graph showing that when S_{SPGR} vs. α_{T} curves are calculated using T₁ and ρ values derived from FIG. 1a, there is no obvious divergence between the theoretical curves and the image data;

FIG. 2a is a Pulse Timing Diagram for an example IR-SPGR sequence to acquire a data set for a plane in k-space, half a plane at a time;

FIG. 2b depicts a Pulse Timing Diagram for an example SPGR sequence;

FIG. 3a depicts residuals between predicted and measured IR-SPGR signal intensities as a function of κ;

FIG. 3b is an expanded view of the 0.5≦κ≦1.5 region of FIG. 3a;

FIG. 4a depicts tri-planar views of a uniform sphere phantom T₁ maps without B₁⁺ field correction;

FIG. 4b depicts tri-planar views of a uniform sphere phantom T₁ maps with B₁⁺ field correction;

FIG. 4c is a graph of the coronal profiles through the B₁⁺ corrected and uncorrected maps;

FIG. 4d is a graph of the axial profiles through the B₁⁺ corrected and uncorrected maps;

FIG. 5 is a comparison of two whole-brain T₁ maps acquired using DESPOT1 and DESPOT-HIFI methods; and

FIG. 6 is a further comparison of maps acquired using DESPOT1 and DESPOT-HIFI.

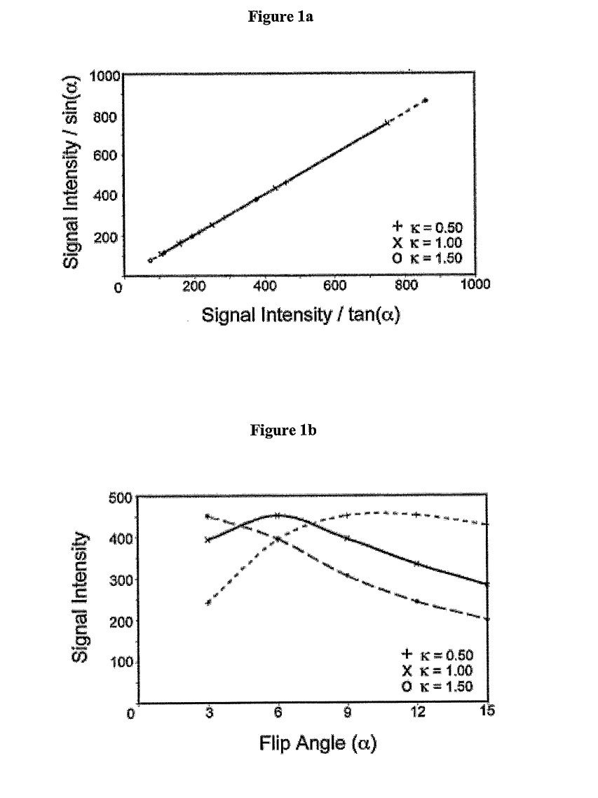

### DETAILED DESCRIPTION

An example will be described in relation to the DESPOT1 T₁ mapping approach discussed above.

This example comprises acquiring an additional inversion-prepared spoiled gradient echo (IR-SPGR) image alongside the conventional dual-angle DESPOT1 data. Therefore at least three data sets are acquired: a minimum of one IR-SPGR data set and DESPOT1 data which is two SPGR data sets. From this combined data, κ (the factor accounting for the B₁⁺ field inhomogeneity) is found which means that both B₁⁺ and T₁ may be readily determined with high accuracy.

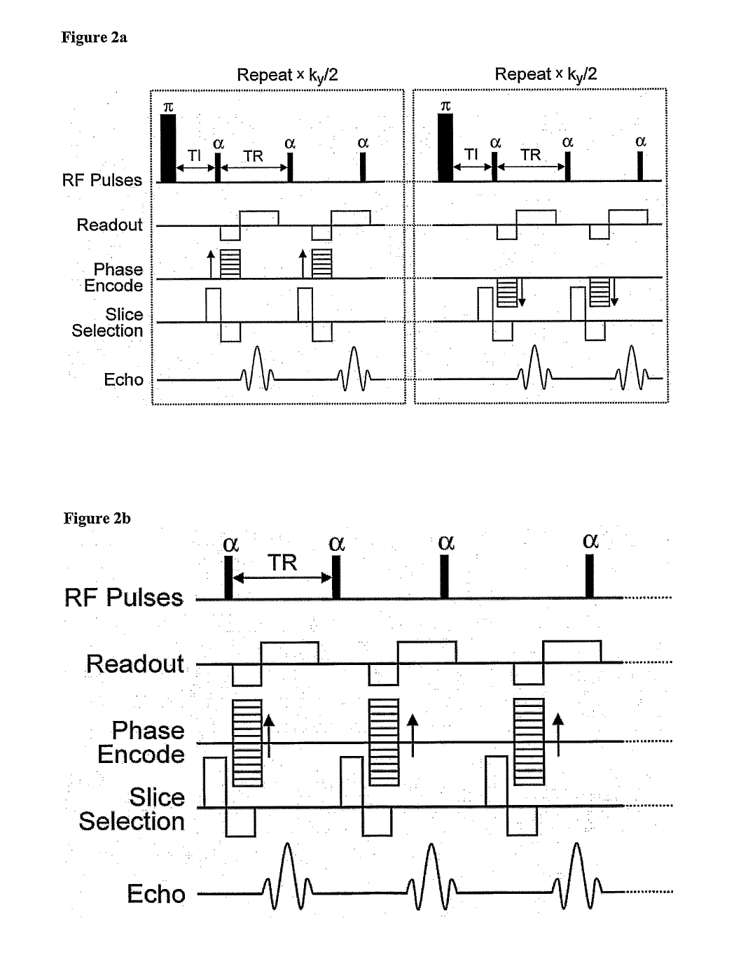

As shown in FIG. 2a, IR-SPGR involves the application of a first preparatory pulse, which is optimally a 180 degree inversion pulse, followed by a train of second RF pulses, preferably having flip angles of less than 30 degrees. During this, data is acquired to give a first data set to define a sample in k-space. In the example show in FIG. 2a, two inversion pulses are used to acquire a data set for a k_{y} plane in k-space. Half of the k_{y} plane is acquired following each inversion pulse and excitation angles of the RF pulses are kept small (less than 10°) with short inter-pulse delays (repetition times, TR) to minimize perturbation of longitudinal magnetization recovery.

FIG. 2b depicts an SPGR sequence which may be used to obtain the second and third data sets.

To eliminate T₂ effects, the transverse magnetization is spoiled prior to each RF pulse. As the RF pulse train perturbs the recovery of the longitudinal magnetization, the measured IR-SPGR signal intensity is a complex function of T₁, proton density, flip angle and RF pulse number. However, if low angle pulses (generally less than 15 degrees) are used such that their disturbing effect may be assumed to be negligible, the measured IR-SPGR signal can be approximated by the IR signal equation modulated by the sine of the low angle pulse,

S_{IR-SPGR}=π[1−INVexp(−TI/T₁)+exp(−Tr/T₁)] sin κα [5]

where INV=1−cos κπ, and Tr is the time between inversion pulses.

As mentioned above, the DESPOT1 T₁ mapping method comprises acquiring at least two SPGR data sets, with sets of third and fourth pulses, over a range of flip angles (α) with constant repetition time (TR). By re-writing the general SPGR signal equation in the linear form Y=mX+b,

$$\frac{{S}_{SPGR}}{sin {α}_{T}} = \frac{{S}_{SPGR}}{tan {α}_{T}} {E}_{1} + ρ ( 1 - {E}_{1} ) , \qquad [ 1 ]$$

T₁ and ρ may be readily determined from the slope and intercept of the S_{SPGR}/sin α vs. S_{SPGR}/tan α curve as,

T₁=−TR/log(m) [2]

and

ρ=b/(1−m). [3]

From the combined multi-angle DESPOT1 and IR-SPGR data, a unique solution for κ, T₁ and ρ can be found through the process of minimizing the residuals between the predicted and measured IR-SPGR and SPGR signal intensities. To simplify the fitting routine, it is possible to make use of the fact that for any value of κ, T₁ and ρ can be determined from the multi-angle DESPOT1 data. The problem, therefore, can essentially be viewed as a single parameter fit for K with residuals calculated only with respect to the IR-SPGR data.

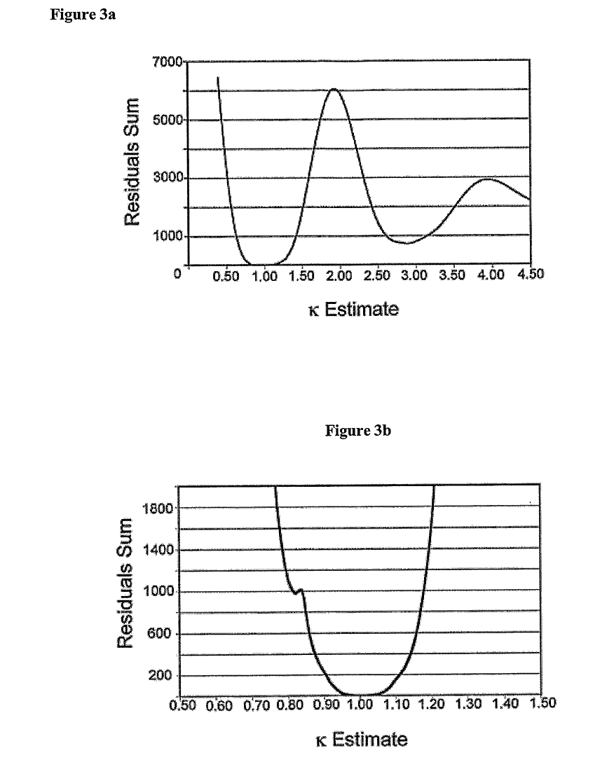

Determination of κ in this manner is demonstrated in FIG. 3, showing noise-free IR-SPGR and DESPOT1 data generated assuming the following parameters: IR-SPGR: TI=150 ms, Tr=342 ms, α_{T}=α_{P}=10°, INV=2, DESPOT1 data with TR=5 ms, α_{T}=α_{P}=3°, 9° and 14°, assuming T₁=1200 ms and ρ=1000. T₁ and ρ values were determined from the DESPOT1 data for different values of κ from 0.5 to 4.5 and these values were substituted into Eqn. [5] to predict the IR-SPGR signal intensity. The sums of the squared differences (residuals) between the predicted and measured IR-SPGR signal intensities as a function of κ are shown in FIG. 3a, with the minimum occurring at κ=1, as expected. FIG. 3b shows a close up of the 0.5≦κ≦1.5 region of FIG. 3a. The combination of IR-SPGR and SPGR allows unambiguous determination of T₁, ρ and κ.

In addition to the global maxima centered at κ=1.00 shown in FIG. 3, an additional local minimum is also observed at κ=˜3. Additional minima occur at approximate ‘harmonics’ of the cos(κπ) term in Eqn. [5]. Thus, although it is possible to calculate κ from just a single IR-SPGR image, under low signal-to-noise ratio (SNR) conditions, two or more data-sets may be preferable to provide more reliable calculation of the global minima and, therefore, more robust κ determination.

In the method according to this example, which may be known as DESPOT1-HIFI, or, DESPOT1 with High-speed Incorporation of RF Field Inhomogeneities, the choice of inversion time may provide optimal T₁ estimate accuracy and precision over a range of κ. Assuming nominal values of 1200 ms for T₁ and ρ=1 (representing an average T₁ of white and grey matter at 3 T, T₁ accuracy and precision have been evaluated from combined theoretical DESPOT1-HIFI data comprised of two SPGR images with different flip angles and either one or two IR-SPGR data-sets with differing inversion times. The IR-SPGR data were generated over the TI range from 10 ms to 500 ms, while κ was varied from 0.3 to 1. Additional sequence-specific parameters were: IR-SPGR: α_{T}=κ10° and Tr=192 ms+TI, SPGR: TR=5 ms and α_{T}=κ3° and κ9°.

The results of this show that, to minimize the scan time for a single inversion time, the optimum inversion time is 250 ms. For dual inversion times, the T₁ accuracy is maximised for all κ for the TI region between 250 ms and 350 ms. As it is generally desirable to maximize the signal difference between the two IP-SPGR measures, the optimum dual inversion times are 250 ms and 350 ms.

DESPOT1-HIFI data have been acquired for uniform sphere phantoms using the following IR-SPGR and SPGR parameters: IR-SPGR: TE/TR=1 ms/3.1 ms, TI=250 ms, Tr=448 ms, α_{P}=10°, BW=±41.67 kHz, SPGR: TE/TR=1.4 ms/5.1 ms, α_{P}=3° and 9°, BW=±27.7 kHz. FOV and matrix size of the DESPOT1-HIFI data were 25 cm×25 cm×18 cm and 256×256×180, respectively. To minimize the acquisition time, the IR-SPGR data were acquired with half the spatial resolution (in all 3 directions) of the SPGR data and zero-padded to the full resolution prior to Fourier reconstruction. Voxel-wise T₁ values were estimated using the DESPOT1-HIFI approach, as well as with the conventional, non-B₁⁺ corrected DESPOT1 method. From the sphere DESPOT1 and DESPOT1-HIFI T₁ maps, profiles along all three orthogonal directions were calculated and compared. To evaluate the accuracy of the DESPOT1-HIFI T₁ estimates, mean values where determined from regions of interest placed within each tube and compared with the reference FSE-IR values.

Reference T₁ values were determined from data acquired using a single-slice, 2D inversion-prepared fast spin-echo (FSE-IR) sequence with the following parameters: 25 cm×25 cm×5 mm field of view (FOV), 128×128×1 matrix, echo time/repetition time (TE/TR)=9 ms/6000 ms, TI=(50, 150, 200, 400, 800, 1600, 3200) ms, bandwidth (BW)=±15.65 kHz and echo train length=2.

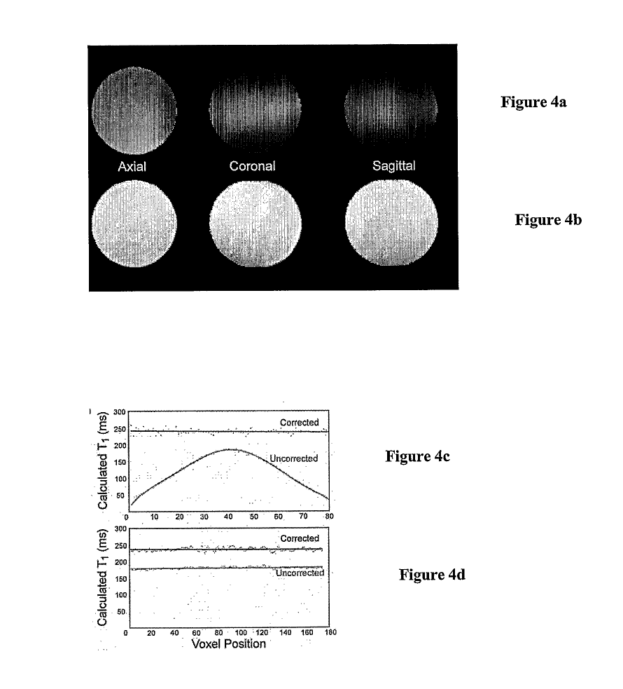

FIG. 4a shows T₁ maps calculated from the uniform sphere phantom using the DESPOT1 method without B₁⁺ correction and FIG. 4b using the DESPOT1-HIFI method. Axial and coronal projects through the B₁⁺ corrected and uncorrected maps are shown in FIGS. 4c and 4d respectively. These illustrations clearly demonstrate the significant T₁ variations which can result from B₁⁺ inhomogeneity associated with both dielectric effects and poor slab profiles. These variations are almost completely removed in the DESPOT1-HIFI T₁ map. The mean T₁, calculated using every non-zero (background) voxel in the image, was found to agree strongly with the reference T₁ value calculated from multiple TI time FSE-IR data.

To assess the in vivo performance of the method, sagittally-oriented whole-brain DESPOT1-HIFI data have been acquired of two healthy volunteers (ages: 24 and 26) with the following parameters: FOV=25 cm×19 cm×18 cm, matrix=256×192×180, IR-SPGR: TE/TR=1 ms/2.8 ms, TI=250 ms, Tr=430 ms. α_{P}=10°, BW=±41.67 kHz, SPGR: TE/TR=1.3 ms/4.8 ms, α_{P}=3° and 9°, BW=±31.3 kHz. Total imaging time for each volunteer was approx. 6.5 minutes, with the IR-SPGR collection requiring just over 1 minute. The IR-SPGR data were acquired with half the spatial resolution of the SPGR data and zero-padded prior to Fourier reconstruction. Reference T₁ values for each volunteer were also determined from axially-oriented FSE-IR data acquired during the same scan session. Voxel-wise T₁ values were calculated from the DESPOT1-HIFI and FSE-IR data and comparison were made between mean values calculated for frontal white matter, caudate nucleus, putamen, and globus pallidus.

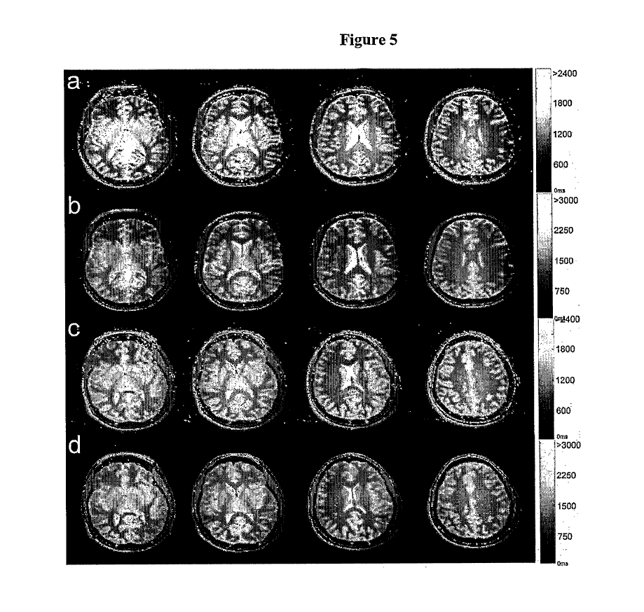

In vivo volunteer results are shown in FIG. 5. Here, representative axial and sagittal slices through the B₁ corrected and uncorrected T₁ volumes are shown for each of two volunteers. Data for the first volunteer is shown in a (DESPOT1) and b (DESPOT1-HIFI) while data from the second volunteer is shown in c (DESPOT1) and d (DESPOT1-HIFI) respectively (with different scales being used for the DESPOT1 and DESPOT1-HIFI values). From visible inspection, the spatial uniformity and hemisphere symmetry of the T₁ values is clearly evident in the corrected maps. T₁ valued within the uncorrected DESPOT1 maps are significantly reduced compared with the DESPOT1-HIFI values and exhibit a ‘Gaussian’ appearance, with the center region bright and tampering off towards the periphery. Comparison of tissue T₁ DESPOT1-HIFI with reference FSE-IR values demonstrates close agreement between the two sets of measurements.

This example provides a quick and unencumbered method to account for B₁⁺ field variations in DESPOT1 involving the acquisition of one or more IR-SPGR data-sets in addition to the conventional dual-angle DESPOT1 data. Near perfect correction for flip angle variations is enabled while requiring minimal additional scan time (in the examples shown, less than 1 minute) and without adversely affecting the precision of the T₁ estimates. Both the calculated B₁⁺ field map and the corrected T₁ map are obtained in a clinically feasible time of less than 10 minutes. More specifically it has been demonstrated that for DESPOT1-HIFI, whole-brain, high spatial resolution (1 mm³ isotropic voxels) combined B₁⁺ and T₁ maps are possible with a combined acquisition time of less than 10 minutes. Compared with reference FSE-IR measurements, mean error in the derived DESPOT1-HIFI T₁ estimates is less than 7% with high reproducibility.

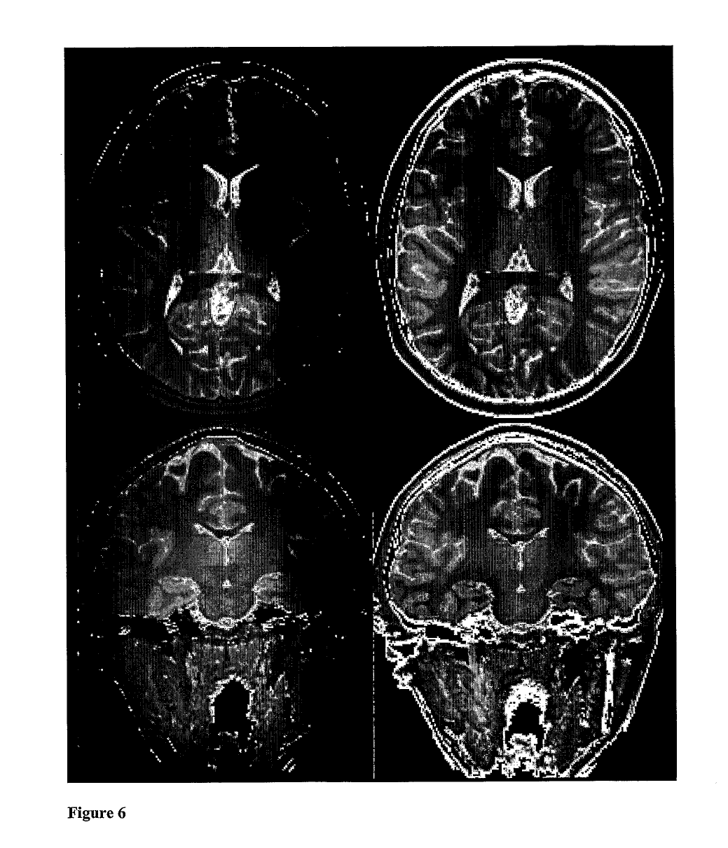

FIG. 6 shows a further comparison of maps acquired using DESPOT1 and DESPOT-HIFI. The images in the left column are uncorrected, while those in the right column have been corrected. The images are of 0.9 mm isotropic voxel dimensions and the corrected images took a total of 14 minutes to acquire (12 for the uncorrected data. The correction does not have any noticeable effect on the signal-to-noise ratio of the images. The 14 minute acquisition is the time it currently takes to acquire the ‘conventional’ structural image clinically, usually with voxel dimensions of 1 mm×1 mm×1.2 mm. The corrected images have higher resolution and better contrast than conventional images, have no B₁ effects and take the same amount of time to obtain as conventional images.

The B₁⁺ field map obtained can be used to help correct signal inhomogeneities in subsequently acquired data. An example of this is when DESPOT1 is used in combination with DESPOT2 (Driven Equilibrium Single Pulse Observation of T₂) for combined T₁ and T₂ mapping. In DESPOT2, T₂ is determined from a series of fully-balanced steady-state free precession images acquired with constant TR and incremented flip angle. As with DESPOT1, accurate T₂ determination with DESPOT2 relies on correct knowledge of α_{T}. In this instance, the B₁⁺ field map calculated with DESPOT1-HIFI may be directly used to determine the transmitted DESPOT2 flip angles.

The example method may be used solely to obtain the B₁⁺ field map without using the T₁ data also obtained in the process. If this is the case the resolution need not be as high as when the T₁ data is also required. In both cases, the resolution required depends on the intrinsic B₁ field variation. While the example method above calculates B₁⁺ field map data by minimizing the residuals between predicted and measured IR-SPGR and SPGR signal intensities, alternative calculation methods may be used such as calculating the B₁⁺ field map data from the at least three data sets acquired by performing a multi-parameter fit for all values for all of the data. The output B₁⁺ field map data may be used to dynamically generate further RF pulses to minimise variation in B₁⁺ field.

The example method may usually be performed with the underlying assumption that the spatial variations in the inversion pulse of IR-SPGR sequence are proportional to the variations in the lower angle pulses. In the example discussed above, similarly designed SLR RF pulses were employed for the inversion and low angle pulses, such that χ=κ, but the present invention is not limited to this case.

In cases where an adiabatic or composite inversion pulse is used, the assumption is not true and the deviations in the flip angle magnitudes become independent, i.e.,

S_{IR-SPGR}=ρ[1−(1−cos χπ)exp(−TI/T₁)+exp(−Tr/T₁)] sin κα [6]

where χ denotes the spatial variation in the inversion pulse, and χ≠κ. Under these conditions, it may be necessary to determine κ and χ independently. This process may be simplified in the case of a well-designed adiabatic pulse in which χ may be assumed to be approximately 1.00.

While the example described above uses a 180 degree inversion pulse and SPGR signals, the invention is not restricted to these examples. A first RF pulse with a flip angle of 90 degrees or above may be used, including an angle greater than 360 degrees. Although the optimum flip angle for the second RF pulses which are part of the IR-SPGR signal is less than 30 degrees, angles, for example, less than 100 degrees may be used. For the third and fourth RF pulses which are part of the DESPOT1 SPGR signals, flip angles of any angle may be used.

The example method can be used with any T₁ weighted imaging protocol and does not have to comprise DESPOT1. The at least three data sets do not have to be acquired by IR-SPGR and two SPGR but may be acquired by other techniques known to the skilled person. Other techniques include Progressive Saturation, Look-Locker, accelerated Look-Locker, TOMROP, FLASH, inversion-prepared FLASH, snapshot FLASH (FLASH can also be called spoiled FLASH), inversion-prepared fully-balanced steady-state free precession (SSFP or TrueFISP or FISP or PSIF or FIESTA or FFSE), inversion recovery (inversion recovery echo planar imaging), saturation recovery (saturation recovery echo planar imaging). Such techniques have many different names and the present invention is not limited to any particular subset of these. The present invention is not limited to clinical techniques and can also be used with, for example, geophysical techniques.

It is not essential that the transverse magnetisation is spoiled and if the transverse magnetization is spoiled this does not have to be with a gradient magnetic field. Alternatively the transverse magnetisation may be spoiled by varying the phase of the subsequent RF pulse applied. In the above example, each data set is acquired with a different flip angle, but alternatively, the flip angle may remain constant and instead the repetition time may be varied. In the above example data sets are acquired directly defining samples in k-space, that is, directly giving the Fourier transform of the image, but any appropriate image space may be used. The samples in the image space may be defined by directly acquiring image data in a point by point fashion. Any method of filling the image space may be used, such as Cartesian filling for example by acquiring alternating lines in a linear fashion, or spiral filling starting from the center and spiraling outwards. Lines, planes or volumes in k-space may be acquired.

One example of data set acquisition which differs from the DESPOT1 example is acquisition using one second pulse following a first inversion pulse, in the form of, for example, an echo-planar readout, to acquire the whole of a k-space place plane at once. This is in contrast to the multi-shot approach described above. Second and third data sets may also each be acquired using one pulse, such as in the form of an echo-planar or spiral readout approaches as known by the skilled person. An echo-planar approach means that any flip angle may be used.

Although only three data sets are necessary, further data sets may be acquired. For the example of IR-SPGR+2 SPGR, further IR-SPGR data sets may be acquired with at least one of the following altered: flip angle for the first preparatory pulse, the time delay following the first pulse before the train of second pulses is applied, the time between the second pulses (repetition time) and the flip angle of the second pulses. Similarly, the number of second and third SPGR data sets acquired may be increased from two, varying at least one of the pulse repetition time and the flip angle.

While this example accounts for B₁⁺ field effects, variations in the B₁ receive field (BD can also cause signal intensity modulations throughout the image. Unlike B₁⁺ effects, however, variations in B₁⁻ can be incorporated into the ρ term and therefore do not result in deviations of the derived T₁ estimates. For applications where accurate proton density estimates are desired, these effects will require an addition correction, usually accomplished by the acquisition of two low spatial resolution images using a large homogeneous body coil and, in neuroimaging applications, a head coil.

The present invention enables a rapid approach for B₁⁺ field mapping, which may be incorporated into a rapid approach for combined B₁⁺ field and T₁ mapping. This allows the highly efficient T₁ mapping methods to be performed at high field strengths, such as 3 T and above, or with small non-symmetric surface RF coils.

1. A method of mapping a radiofrequency (RF) magnetic field (B₁⁺) transmitted to a magnetic resonance imaging (MRI) specimen, the method comprising:
applying a first RF pulse having a first excitation angle to the specimen and at a first time period after applying the first pulse applying one or more second RF pulses each having a second excitation angle to the specimen, with a second time period between second pulses, to obtain a first data set defining a first sample of an image space;
applying one or more third RF pulses each having a third excitation angle to the specimen, with a third time period between third pulses, to obtain a second data set defining a second sample of the image space;
applying one or more fourth RF pulses each having a fourth excitation angle to the specimen, with a fourth time period between fourth pulses, to obtain a third data set defining a third sample of the image space, wherein the fourth excitation angle is different to the third excitation angle and/or the fourth time period is different to the third time period;
calculating B₁⁺ field map data from at least the three data sets; and
outputting the B₁⁺ field map data.

2. A method according to claim 1, wherein the image space is k-space.

3. A method according to claim 1, wherein the samples of the image space are one-dimensional, two-dimensional or three-dimensional.

4. A method according to claim 1, wherein the first RF pulse is an inversion pulse.

5. A method according to claim 4, wherein the inversion pulse has an excitation angle of 180 degrees.

6. A method according to claim 1, further comprising spoiling residual transverse magnetisation resulting from at least one of the steps of applying first, second, third or fourth pulses.

7. A method according to claim 6, wherein spoiling residual transverse magnetization comprises at least one of applying a gradient magnetic field subsequent to the application of the RF pulse resulting in the residual transverse magnetisation and varying the phase of the RF pulse applied subsequent to the RF pulse resulting in the residual transverse magnetisation, relative to the phase of the RF pulse resulting in the residual transverse magnetisation.

8. A method according to claim 6, wherein applying a first pulse and one or more second pulses and spoiling residual transverse magnetisation are comprised by obtaining an inversion recovery spoiled gradient recalled (IR-SPGR) signal.

9. A method according to claim 6, wherein the steps of applying one or more third pulses and spoiling residual transverse magnetisation are comprised by the stop of obtaining a first SPGR signal.

10. A method according to claim 6, wherein applying one or more fourth RF pulses is comprised by obtaining a second SPGR signal.

11. A method according to claim 1, wherein applying one or more third pulses and spoiling residual transverse magnetization are comprised by obtaining a first SPGR signal, applying one or more fourth RF pulses is comprised by obtaining a second SPGR signal, and obtaining a first and second SPGR signal are comprised by obtaining DESPOT1 data.

12. A method according to claim 1, wherein calculating B₁⁺ field map data from at least the three data sets comprises the steps of:
obtaining predicted data for the first data set from the second and third data sets; and
comparing the predicted data with the first data set.

13. A method according to claim 12, wherein obtaining predicted data comprises:
calculating T₁ (longitudinal relaxation time) and ρ (a factor proportional to the equilibrium longitudinal magnetization including at least a factor of electronic amplifier gain or receive coil sensitivity effects by inserting the combined second and third data set into the following equation;
$$\frac{S 1}{sin {α}_{T}} = \frac{S 1}{tan {α}_{T}} {E}_{1} + ρ ( 1 - {E}_{1} ) ,$$
wherein
S1 is the combined second and third data sets;
α_{T} is the transmitted angle of excitation
E₁=E=exp(−TR/T₁) where TR is the time delay between the third pulse and the repeated third pulse; and
calculating predicted data for the first data set as a function of a B₁⁺ field variation factor, κ, from the obtained T₁ and ρ and the following equation:
S2=ρ[1−INVexp(−TI/T₁)+exp(−Tr/T₁)] sin κα
where
INV=1−cos κπ;
Tr is the time between second RF pulses;
TI is the time between the first pulse and the second pulse.

14. A method according to claim 12, wherein comparing the predicted data with the first data set comprises calculating residuals for the predicted data and the first data set as a function of κ.

15. A method according to claim 1, wherein calculating B₁⁺ field map data from at least three data sets comprises performing a multi-parameter fit for a plurality of samples from the at least three data sets.

16. A method according to claim 1, further comprising obtaining at least one further first, second or third data set.

17. A method according to claim 16, comprising obtaining at least one further first data set with at least a different first time period, first excitation angle, second time period or second excitation angle.

18. A method according to claim 16, comprising obtaining at least one further second data set with at least a different third time period or third excitation angle.

19. A method according to claim 16, comprising obtaining at least one further third data set with at least a different fourth time period or fourth excitation angle.

20. A method according to claim 1, further comprising correcting for a B₁⁻ field.

21. A method according to claim 1, the method further comprising:
calculating T₁ (longitudinal relaxation time) map data from the three data sets; and
outputting the T₁ map data.

22. A method according to claim 1, further comprising using the output B₁⁺ field map data to dynamically generate a further RF pulse that minimises variation in B₁⁺ field.

23. A method according to claim 1, the method further comprising applying the output B₁⁺ field map data to an MRI image to produce a corrected image.

24. A method of correcting, in an MRI image, for inhomogeneities in a magnetic field (B₁⁺) transmitted to a MRI specimen, the method comprising:
acquiring B₁⁺ field map data by:
applying a first RF pulse having a first excitation angle to the specimen and at a first time period after applying the first pulse applying one or more second RF pulses each having a second excitation angle to the specimen, with a second time period between second pulses, to obtain a first data set defining a first sample of an image space,
applying one or more third RF pulses each having a third excitation angle to the specimen, with a third time period between third pulses, to obtain a second data set defining a second sample of the image space,
applying one or more fourth RF pulses each having a fourth excitation angle to the specimen, with a fourth time period between fourth pulses, to obtain a third data set defining a third sample of the image space, wherein the fourth excitation angle is different to the third excitation angle and/or the fourth time period is different to the third time period,
calculating B₁⁺ field map data from at least the three data sets, and
outputting the B₁⁺ field map data, and
applying B₁⁺ field map data to MRI image data to produce a corrected image.
